(19) United States
(12) Patent Application Publication
(10) Pub. No.: US 2020/0027953 A1
(43) Pub. Date: Jan. 23, 2020

(54) SCHOTTKY DIODE WITH HIGH BREAKDOWN VOLTAGE AND SURGE CURRENT CAPABILITY USING DOUBLE P-TYPE EPITAXIAL LAYERS

(71) Applicants: NA REN, LOS ANGELES, CA (US); ZHENG ZUO, LOS ANGELES, CA (US); RUIGANG LI, LOS ANGELES, CA (US)

(72) Inventors: NA REN, LOS ANGELES, CA (US); ZHENG ZUO, LOS ANGELES, CA (US); RUIGANG LI, LOS ANGELES, CA (US)

(73) Assignee: AZ Power, Inc, CULVER CITY, CA (US)

(21) Appl. No.: 16/412,196

(22) Filed: May 14, 2019

Related U.S. Application Data
(60) Provisional application No. 62/699,649, filed on Jul. 17, 2018.

(51) Int. Cl. H01L 29/16; H01L 29/66; H01L 29/872; H01L 29/45

(52) U.S. Cl. CPC H01L 29/1608; H01L 29/45; H01L 29/872; H01L 29/66143

(57) ABSTRACT

A method for manufacturing a Silicon Carbide (SiC) Schottky diode may include steps of providing a substrate; forming a first epitaxial layer with a first conductivity type on top of the substrate; forming a second epitaxial layer with a second conductivity type on top of the first epitaxial layer; forming a third epitaxial layer with the second conductivity type on top of the second epitaxial layer; patterning and etching the second and third epitaxial layers to form a plurality of trenches; depositing a first ohmic contact metal on a backside of the substrate; forming a second ohmic contact metal on top of the second epitaxial layer; forming a Schottky contact metal at a bottom portion of each trench; and forming a pad electrode on top of the Schottky contact metal.

### CROSS-REFERENCE TO RELATED APPLICATIONS

This application claims priority under 35 U.S.C. § 119 (e) to U.S. Provisional Patent Application Ser. No. 62/699,649, filed on Jul. 17, 2018, the entire contents of which are hereby incorporated by reference.

### FIELD OF THE INVENTION

The present invention relates to a Scthottky diode, and more particularly to a Scthottky diode with double P-type epitaxial layers and the manufacturing method thereof without implantation process.

### BACKGROUND OF THE INVENTION

A conventional Schottky diode, referring to FIG. 1, may include an ohmic contact 6, a substrate 1, an epitaxial layer 2, and a Schottky contact metal 5. The Schottky contact metal 5 can be made of aluminum, titanium, nickel, silver or other metals. The substrate and epitaxial layers are usually doped with N-type impurity. A Schottky junction is formed between the Schottky contact metal 5 and epitaxial layer 2.

The Silicon Carbide (SiC) Schottky diode is widely accepted in recent years as it features the benefits of Schottky barrier and wide band-gap material. As a majority carrier device, it has advantages of high voltage, high speed and low forward voltage since there is no reverse recovery current.

For a pure Schottky barrier diode, a major problem is that it's surge current capability is low when compared with PN junction diode. To address this problem, junction barrier Schottky (JBS) diode or merged PN junction Schottky (MPS) diode structures were proposed.

A conventional JBS/MPS diode, referring to FIG. 2, may include ohmic contact 16, substrate 11, epitaxial layer 12, Schottky contact metal 15 and P-type region 14, which is usually produced by ion implantation.

Is this structure, the P-type region 14 can form a PN junction which can be activated in surge condition to gain surge current capability. In general, the JBS and MPS diodes use ion implantation process to introduce the impurity region. However, ion implantation can damage the high-concentration impurity region. Furthermore, a high temperature process is needed for the conventional JBS/MPS diode, which is not compatible with the manufacturing process, and expensive production installations and production process are usually required for manufacturing the JBS/MPS diode.

Therefore, there remains a need for a new and improved fabrication technique to generate a Schottky diode to overcome the problems stated above.

### SUMMARY OF THE INVENTION

The present invention introduces a method to fabricate the Schottky barrier diode with high breakdown voltage and surge current capability by using double P-type epitaxial semiconductor layers. with the elimination of ion implantation and activation annealing process, the semiconductor device can be produced through a low-temperature process, in which the ohmic contact annealing can be done at 1000° C. or less, and the Schottky contact annealing at 600° C. Accordingly, expensive manufacturing installations and complicated production process are not required, so the production cost of the semiconductor device can be significantly reduced.

In one aspect, a Silicon-Carbide (SiC) Schottky diode may include an ohmic contact metal, an N⁺ substrate, an N⁻ epitaxial layer, a P⁻ epitaxial layer, a P⁺ epitaxial layer, a first electrode, a second electrode, and a third electrode.

In one embodiment, the material selected for the ohmic contact metal may include nickel, silver and platinum. The substrate produced from the N⁺ type SiC substrate is located on the top of the ohmic contact metal. In one embodiment, the impurity concentration is about 10¹⁸˜10²⁰ atoms/cm³.

In another embodiment, the epitaxial layer produced from the N⁻ type SiC is located on the top of the substrate. It has an impurity concentration lower than that of the SiC substrate. For example, the impurity concentration of the epitaxial layer is about 10¹⁵˜10¹⁷ atoms/cm³.

The epitaxial layer produced from P⁻ type SiC is located on top of the epitaxial layer. In one embodiment, the thickness of the epitaxial layer is about 0.1˜2 μm, and the impurity concentration is about 10¹⁶˜10¹⁸ atoms/cm³.

The epitaxial layer produced from P⁺ type SiC is located on top of the epitaxial layer. In one embodiment, the thickness of the epitaxial layer is about 1˜5 μm, and the impurity concentration is about 10¹⁸˜10²¹ atoms/cm³.

It is noted that a trench with a rounded corner is formed in the P⁺ type epitaxial layer and P⁻ type epitaxial layer, and the corner portion in which a side face and a bottom surface of the recess intersect each other located in the P⁻ type SiC layer. The center portion of the trench ends at the surface of the N⁻ type epitaxial layer, which means the N⁻ type SiC layer can be exposed in the middle of the trench bottom.

A first electrode is provided while being in contact with the upper surface of the P⁺ type SiC epitaxial layer. The P⁺ type SiC epitaxial layer is in ohmic contact with the first electrode. Any material can be used as the first electrode as long as the material is in ohmic contact with the P⁺ type SiC, such as nickel, aluminum and titanium.

A second electrode is provided in the bottom surface of the trench, and forms a Schottky junction between the second electrode and the exposed N⁻ type SiC epitaxial layer. Any material can be used as the second electrode as long as the material is in Schottky contact with N⁻ type SiC, such as titanium, nickel, aluminum, silver or tungsten.

A pad electrode that constitutes an anode electrode is formed on the second electrode. In one embodiment, the thickness of the pad electrode may be 3˜6 μm, and the material may be aluminum if aluminum wire bonding is performed.

An end portion of the Schottky diode is formed into junction termination extension (JTE) structure, in which, the upper P⁺ type epitaxial layer is etched away and part of P⁻ type epitaxial layer is remained as the JTE region. The impurity concentration and the width of the remained P⁻ type epitaxial layer in the end portion is optimized to achieve high breakdown voltage. The blocking efficiency is very sensitive to the impurity concentration of the JTE region. With the epitaxially grown P⁻ type layers, the present invention has an advantage of high accuracy and controllability of the impurity concentration, which is important in implantation process.

### BRIEF DESCRIPTION OF THE DRAWINGS

FIG. 1 is a prior art disclosing a conventional Schottky diode.

FIG. 2 is a conventional Junction Barrier Schottky (JBS) diode or Merged PN junction Schottky (MPS) diode.

FIG. 3 illustrates a schematic view of a Scthottky diode with double P-type epitaxial layers in the present invention.

FIGS. 4A to 4I illustrate a manufacturing process of a method for manufacturing a Silicon Carbide (SiC) Schottky diode with double P-type epitaxial layers in the present invention.

FIG. 5 illustrates a flow diagram of a method for manufacturing a Silicon Carbide (SiC) Schottky diode with double P-type epitaxial layers in the present invention.

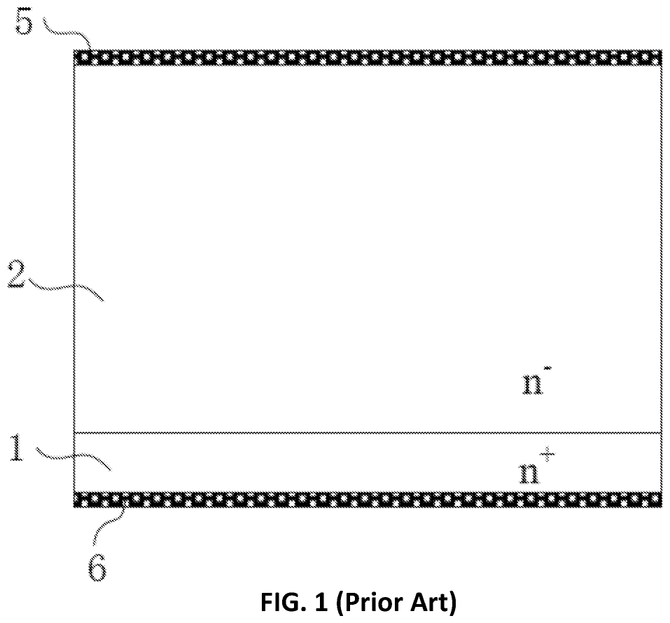

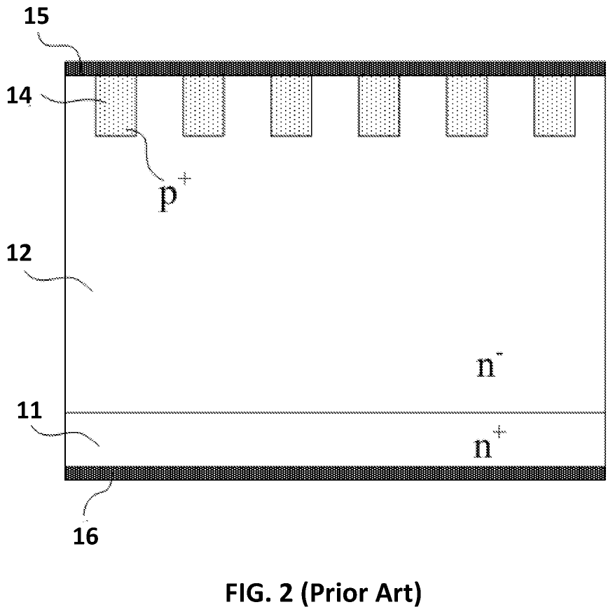

### DETAILED DESCRIPTION OF THE INVENTION

The detailed description set forth below is intended as a description of the presently exemplary device provided in accordance with aspects of the present invention and is not intended to represent the only forms in which the present invention may be prepared or utilized. It is to be understood, rather, that the same or equivalent functions and components may be accomplished by different embodiments that are also intended to be encompassed within the spirit and scope of the invention.

Unless defined otherwise, all technical and scientific terms used herein have the same meaning as commonly understood to one of ordinary skill in the art to which this invention belongs. Although any methods, devices and materials similar or equivalent to those described can be used in the practice or testing of the invention, the exemplary methods, devices and materials are now described.

All publications mentioned are incorporated by reference for the purpose of describing and disclosing, for example, the designs and methodologies that are described in the publications that might be used in connection with the presently described invention. The publications listed or discussed above, below and throughout the text are provided solely for their disclosure prior to the filing date of the present application. Nothing herein is to be construed as an admission that the inventors are not entitled to antedate such disclosure by virtue of prior invention.

As used in the description herein and throughout the claims that follow, the meaning of “a”, “an”, and “the” includes reference to the plural unless the context clearly dictates otherwise. Also, as used in the description herein and throughout the claims that follow, the terms “comprise or comprising”, “include or including”, “have or having”, “contain or containing” and the like are to be understood to be open-ended, i.e., to mean including but not limited to. As used in the description herein and throughout the claims that follow, the meaning of “in” includes “in” and “on” unless the context clearly dictates otherwise.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the embodiments. As used herein, the term “and/or” includes any and all combinations of one or more of the associated listed items.

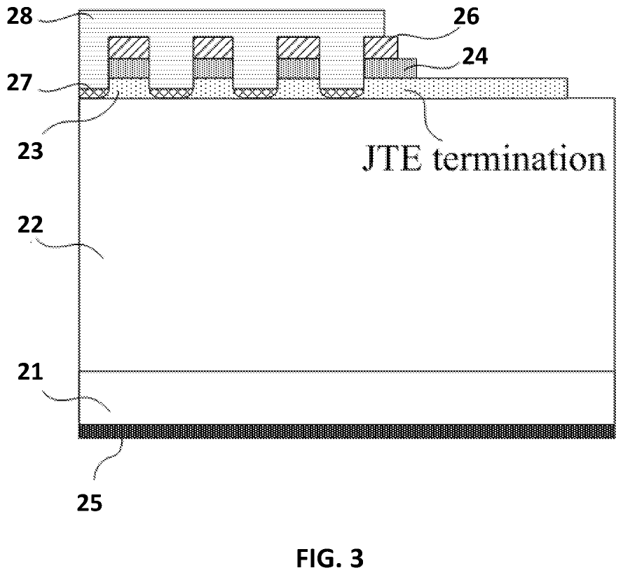

In one aspect as shown in FIG. 3 that illustrates a cross sectional view of the Silicon-Carbide (SiC) Schottky barrier diode without implantation process. The SiC Schottky diode may include an ohmic contact metal 25; an N⁺ substrate 21; an N⁻ epitaxial layer 22; a P⁻ epitaxial layer 23; a P⁺ epitaxial layer 24; a first electrode 26 in contact with the upper surface of the P⁺ type SiC epitaxial layer 24; a second electrode 27 provided in the bottom surface of the trench, forming a Schottky junction between the second electrode 27 and the exposed N⁻ type SiC epitaxial layer 22; and a third electrode 28.

In one embodiment, the material selected for the ohmic contact metal 25 may include nickel, silver and platinum. The substrate 21 produced from the N⁺ type SiC substrate 21 is located on the top of the ohmic contact metal 25. In one embodiment, the impurity concentration is about 10¹⁸˜10²⁰ atoms/cm³.

In another embodiment, the epitaxial layer 22 produced from the N⁻ type SiC is located on the top of the substrate 21. It has an impurity concentration lower than that of the SiC substrate 21. For example, the impurity concentration of the epitaxial layer 22 is about 10¹⁵˜10¹⁷ atoms/cm³.

The epitaxial layer 23 produced from P⁻ type SiC is located on top of the epitaxial layer 22. In one embodiment, the thickness of the epitaxial layer 23 is about 0.1˜2 μm, and the impurity concentration is about 10¹⁶˜10¹⁸ atoms/cm³.

The epitaxial layer 24 produced from P⁺ type SiC is located on top of the epitaxial layer 23. In one embodiment, the thickness of the epitaxial layer 24 is about 1˜5 μm, and the impurity concentration is about 10¹⁸˜10²¹ atoms/cm³.

It is noted that a trench with a rounded corner is formed in the P⁺ type epitaxial layer 24 and P⁻ type epitaxial layer 23, and the corner portion in which a side face and a bottom surface of the recess intersect each other located in the P⁻ type SiC layer 23. The center portion of the trench ends at the surface of the N⁻ type epitaxial layer 22, which means the N⁻ type SiC layer 22 can be exposed in the middle of the trench bottom.

A first electrode 26 is provided while being in contact with the upper surface of the P⁺ type SiC epitaxial layer 24. The P⁺ type SiC epitaxial layer 24 is in ohmic contact with the first electrode 26. Any material can be used as the first electrode 26 as long as the material is in ohmic contact with the P⁺ type SiC 24, such as nickel, aluminum and titanium.

A second electrode 27 is provided in the bottom surface of the trench, and forms a Schottky junction between the second electrode 27 and the exposed N⁻ type SiC epitaxial layer 22. Any material can be used as the second electrode 27 as long as the material is in Schottky contact with N⁻ type SiC 22, such as titanium, nickel, aluminum, silver and tungsten.

A pad electrode 28 that constitutes an anode electrode is formed on the second electrode 27. In one embodiment, the thickness of the pad electrode 28 may be 3˜6 μm, and the material may be aluminum if aluminum wire bonding is performed.

An end portion of the Schottky diode is formed into junction termination extension (JTE) structure, in which, the upper P⁺ type epitaxial layer 24 is etched away and part of P⁻ type epitaxial layer 23 is remained as the JTE region. The impurity concentration and the width of the remained P⁻ type epitaxial layer 23 in the end portion is optimized to achieve high breakdown voltage. The blocking efficiency is very sensitive to the impurity concentration of the JTE region. With the epitaxially grown P⁻ type layers, the present invention has an advantage of high accuracy and controllability of the impurity concentration, which is important in implantation process.

In the forward mode, the Schottky contact between the second electrode 27 and N⁻ type epitaxial layer 22 at the trench bottom is firstly turned on. As the voltage increases, the PN junction between the P+/P⁻ epitaxial layer and N⁻ epitaxial layer 22 will be activated since the first electrode 26 and the P⁺ epitaxial layer 24 is in ohmic contact. It is noted that the mesa width of the double P-type epitaxial layer (P⁺ epitaxial layer 23 and P⁻ epitaxial layer 24) and the space between adjacent mesas are carefully designed to activate the PN junction early, and then holes can be injected from the P⁺ epitaxial layer 24 to N⁻ drift layer 22. Therefore, conductivity modulation can be achieved to gain surge current capability. With the epitaxially grown P⁺ type SiC layer 23 and P⁻ type SiC layer 24, the present invention can achieve the goal of high injection efficiency since there is no damage to cause the shorten carrier life time and injection efficiency degradation, which is one of the major concerns for ion implantation-based structure.

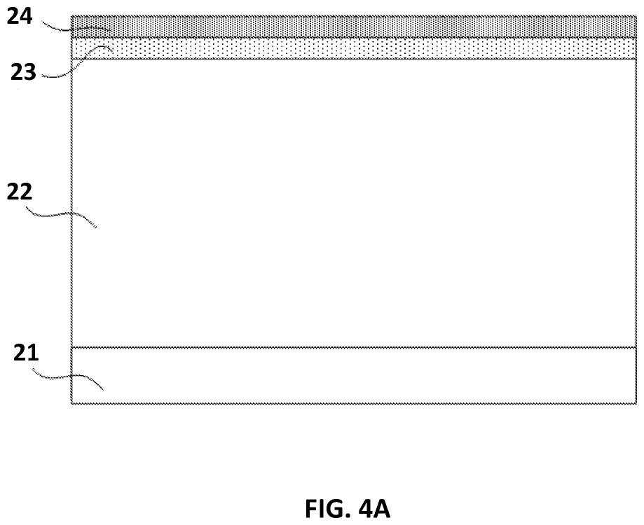

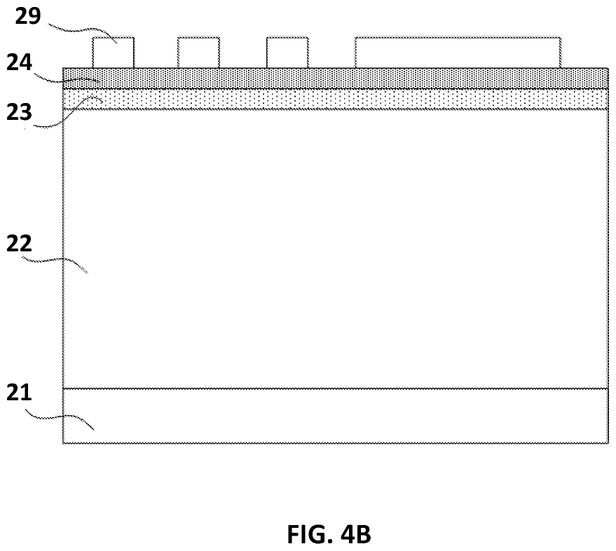

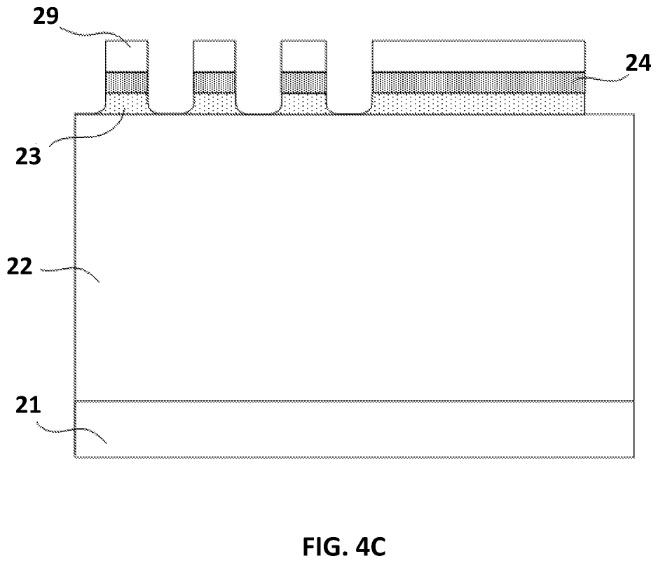

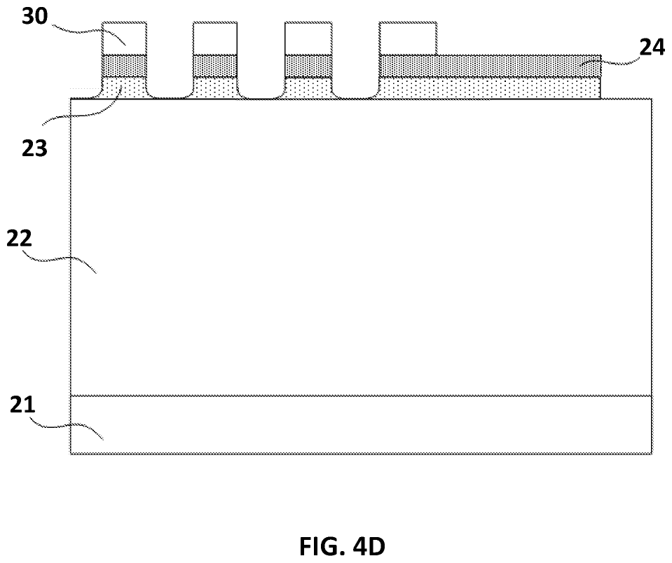

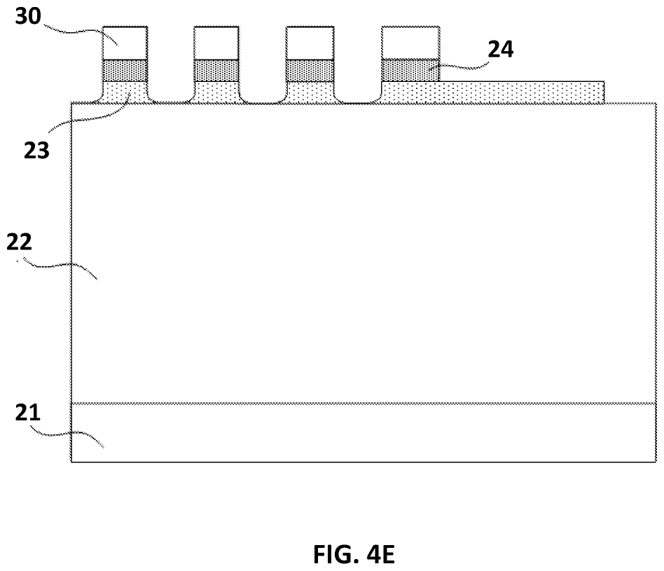

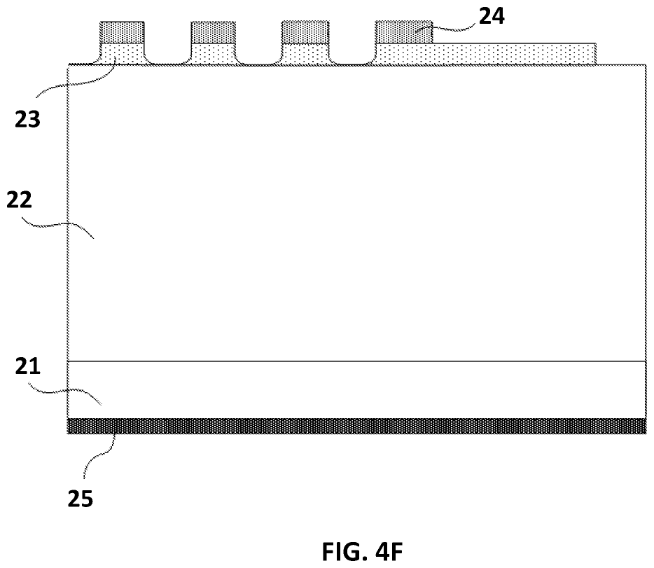

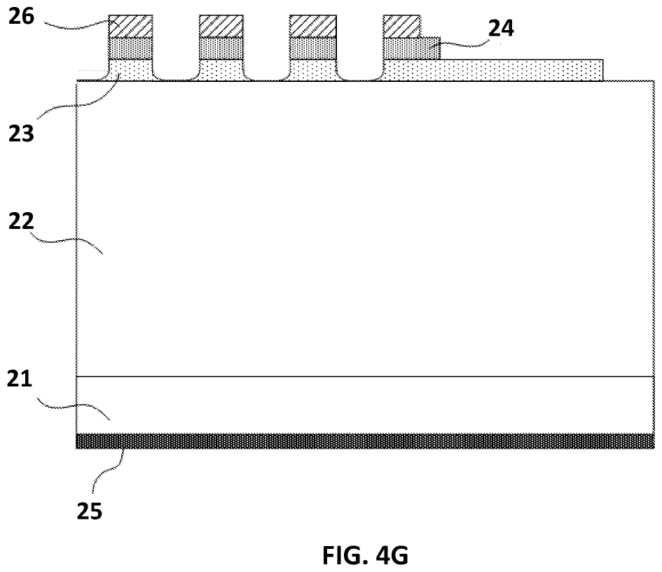

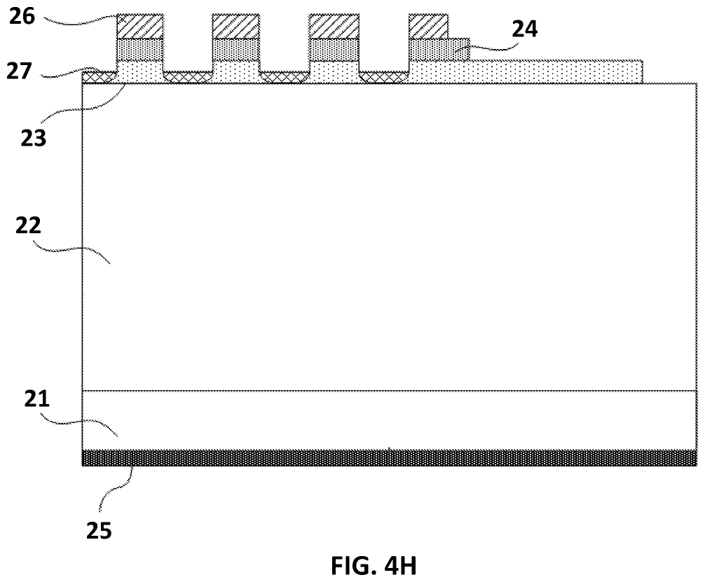

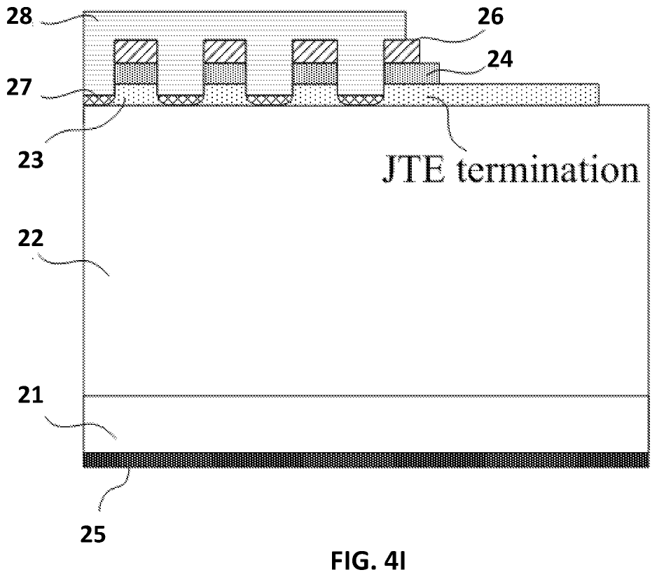

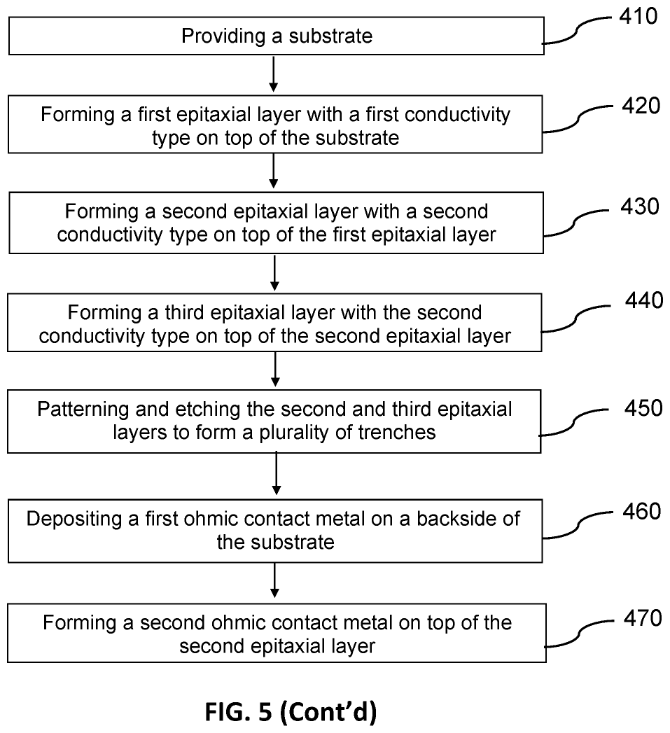

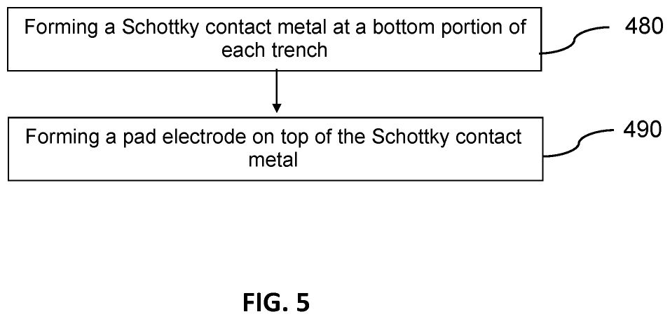

In another aspect, as shown in FIGS. 4A to 4I, a method for manufacturing a Silicon Carbide (SiC) Schottky diode with double P-type epitaxial layers may include steps of providing a substrate 410, forming a first epitaxial layer with a first conductivity type on top of the substrate 420, forming a second epitaxial layer with a second conductivity type on top of the first epitaxial layer 430, forming a third epitaxial layer with the second conductivity type on top of the second epitaxial layer 440, patterning and etching the second and third epitaxial layers to form a plurality of trenches 450, depositing a first ohmic contact metal on a backside of the substrate 460, forming a second ohmic contact metal on top of the second epitaxial layer 470, forming a Schottky contact metal at a bottom portion of each trench 480, and forming a pad electrode on top of the Schottky contact metal 490.

In one embodiment, the substrate 21 is a N⁺ type SiC, and the first epitaxial layer 22 is an N⁻ type SiC layer. In another embodiment, the second epitaxial layer 23 is a P⁻ type SiC layer and the third epitaxial layer 24 is a P⁺ type SiC layer as shown in FIG. 4A.

As shown in FIG. 4B, a first mask layer 29 is deposited and patterned on top of the third epitaxial layer 24 for etching the second and third epitaxial layers 23 and 24, as well as forming a junction termination extension (JTE) region. As shown in FIG. 4C, it is noted that in order to relieve the electric field concentration at the corner of the trench in the reverse mode, smoothing the trench feature with a rounded corner is preferred. It is also noted that the corner of the trench is formed mostly at the second epitaxial layer 23, and the bottom portion is formed at the first epitaxial layer 22, namely the N⁻ type SiC layer, which can be considered an N⁻ type Schottky junction.

As shown in FIGS. 4D and 4E, the first mask layer 29 is removed and a second mask layer 30 is formed and patterned on top of the third epitaxial layer 24 to pattern and etch the third epitaxial layer 24 on top of the JTE region away in the end portion. As shown in FIG. 4F, a first ohmic contact metal 25 is formed at the bottom portion of the substrate 21. In one embodiment, the first ohmic contact metal 25 can be selected from a group including nickel, silver or platinum.

In another embodiment, as shown in FIG. 4G, a second ohmic contact metal 26 can be formed and patterned on top of the third epitaxial layer 24. The second ohmic contact metal 26 can be selected from a group including nickel, aluminum and titanium. In a further embodiment, as shown in FIG. 4H, the step of forming a Schottky contact metal may include a step of depositing a metal on the top of the N⁻ type epitaxial layer 22 to form a Schottky junction between the Schottky contact metal and the N⁻ type epitaxial layer 22.

In still a further embodiment, the step of forming a pad electrode on top of the Schottky contact metal (as shown in FIG. 4I) may include a step of depositing a thick electrode metal on the top of the Schottky contact metal. The thick electrode metal can be aluminum in one embodiment.

According to the present invention, the semiconductor device can be manufactured at low cost with double P− type epitaxially grown layers instead of the ion implantation method. The JTE termination structure can be implemented through the P⁻ type SiC epitaxial layer, and the impurity concentration can be controlled. In the active region, with the rounded trench corner and the P⁻ type epitaxial layer surrounding the corner, the leakage current can be suppressed. As a result, a high breakdown voltage capability can be achieved for this semiconductor device.

Furthermore, with the elimination of ion implantation and activation annealing process, the semiconductor device can be produced through a low-temperature process, in which the ohmic contact annealing can be done at 1000° C. or less, and the Schottky contact annealing at 600° C. Accordingly, expensive manufacturing installations and complicated production process are not required, so the production cost of the semiconductor device can be significantly reduced.

Having described the invention by the description and illustrations above, it should be understood that these are exemplary of the invention and are not to be considered as limiting. Accordingly, the invention is not to be considered as limited by the foregoing description, but includes any equivalent.

What is claimed is:

1. A method for manufacturing a Silicon Carbide (SiC) Schottky diode comprising steps of:
providing a substrate;
forming a first epitaxial layer with a first conductivity type on top of the substrate;
forming a second epitaxial layer with a second conductivity type on top of the first epitaxial layer;
forming a third epitaxial layer with the second conductivity type on top of the second epitaxial layer;
patterning and etching the second and third epitaxial layers to form a plurality of trenches;
depositing a first ohmic contact metal on a backside of the substrate;
forming a second ohmic contact metal on top of the second epitaxial layer;
forming a Schottky contact metal at a bottom portion of each trench; and
forming a pad electrode on top of the Schottky contact metal.

2. The method for manufacturing a Silicon Carbide (SiC) Schottky diode of claim 1, wherein the substrate is a N⁺ type SiC, and the first epitaxial layer is an N⁻ type SiC layer.

3. The method for manufacturing a Silicon Carbide (SiC) Schottky diode of claim 1, wherein the second epitaxial layer is a P⁻ type SiC layer and the third epitaxial layer is a P⁺ type SiC layer.

4. The method for manufacturing a Silicon Carbide (SiC) Schottky diode of claim 1, wherein a junction termination extension (JTE) region is formed by patterning and etching an end portion of the second and third epitaxial layers.

5. The method for manufacturing a Silicon Carbide (SiC) Schottky diode of claim 1, wherein each trench is smoothed with rounded corners to relieve an electric field concentration at the corner of the trench in the reverse mode.

6. The method for manufacturing a Silicon Carbide (SiC) Schottky diode of claim 1, wherein the first ohmic contact metal is selected from a group including nickel, silver and platinum.

7. The method for manufacturing a Silicon Carbide (SiC) Schottky diode of claim 1, wherein the second ohmic contact metal is selected from a group including nickel, aluminum and titanium.

8. The method for manufacturing a Silicon Carbide (SiC) Schottky diode of claim 1, wherein the step of forming a Schottky contact metal includes a step of depositing a metal on the top of the first epitaxial layer to form a Schottky junction between the Schottky contact metal and the first epitaxial layer.

9. A Silicon Carbide (SiC) Schottky diode comprising:
a substrate of a first conductivity type;
an ohmic contact metal deposited on a backside of the substrate;
a first epitaxial layer of the first conductivity layer deposited on top of the substrate;
a second epitaxial layer of a second conductivity type deposited on top of the first epitaxial layer;
a third epitaxial layer of the second conductivity type deposited on top of the second epitaxial layer;
a plurality of trenches formed by etching the second and third epitaxial layers;
a first electrode in contact with an upper surface of the third epitaxial layer;
a second electrode deposited at a bottom portion of the trench, forming a Schottky junction between the second electrode and the first epitaxial layer; and
a third electrode used as an anode electrode formed on top of the second electrode.

10. The Silicon Carbide (SiC) Schottky diode of claim 9, wherein the substrate is a N⁺ type SiC, and the first epitaxial layer is an N⁻ type SiC layer.

11. The Silicon Carbide (SiC) Schottky diode of claim 9, wherein the second epitaxial layer is a P⁻ type SiC layer and the third epitaxial layer is a P⁺ type SiC layer.

12. The Silicon Carbide (SiC) Schottky diode of claim 9, wherein a junction termination extension (JTE) region is formed by patterning and etching an end portion of the second and third epitaxial layers.

13. The Silicon Carbide (SiC) Schottky diode of claim 9, wherein each trench is smoothed with rounded corners to relieve an electric field concentration at the corner of the trench in the reverse mode.

14. The Silicon Carbide (SiC) Schottky diode of claim 9, wherein the first ohmic contact metal is selected from a group including nickel, silver and platinum.

15. The Silicon Carbide (SiC) Schottky diode of claim 9, wherein the second ohmic contact metal is selected from a group including nickel, aluminum and titanium.
